(19) United States
(12) Patent Application Publication
(10) Pub. No.: US 2009/0004825 A1
(43) Pub. Date: Jan. 1, 2009

(54) METHOD OF MANUFACTURING SEMICONDUCTOR SUBSTRATE

(75) Inventors: Takeshi SENDA, Niigata (JP); Hiromichi ISOGAI, Niigata (JP); Eiji TOYODA, Niigata (JP); Akiko NARITA, Niigata (JP); Koji IZUNOME, Niigata (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Covalent Materials Corporation, Shinagawa-ku (JP)

(21) Appl. No.: 11/969,379

(22) Filed: Jan. 4, 2008

(30) Foreign Application Priority Data
Jan. 4, 2007 (JP) 2007-000269
Oct. 25, 2007 (JP) 2007-277183

(51) Int. Cl. H01L 21/46

(52) U.S. Cl. 438/459; 257/E27.111

(57) ABSTRACT

A method of manufacturing a semiconductor substrate having a DSB structure that enables simplification of a manufacturing process by optimizing a total thickness of oxides on surfaces of two wafers before being bonded together is provided. The method comprises a process of preparing a first semiconductor wafer and a second semiconductor wafer, a process of bonding the first semiconductor wafer and second semiconductor wafer when a total of thickness of an oxide on the surface of the first semiconductor wafer and that of an oxide on the surface of the second semiconductor wafer is 0.4 nm or more and 1.0 nm or less, and a process of providing heat treatment to a semiconductor substrate after the process of the bonding and before a process of thinning one of the wafers.

### CROSS-REFERENCE TO RELATED APPLICATION

This application is based upon and claims the benefit of priority from the Japanese Patent Applications No. 2007-000269, filed on Jan. 4, 2007, No. 2007-277183, filed on Oct. 25, 2007; the entire contents of which are incorporated herein by reference.

### BACKGROUND OF THE INVENTION

1. Field of the Invention

The present invention relates to a method of manufacturing a semiconductor substrate, and in particular, relates to a method of manufacturing a semiconductor substrate in which two wafers are directly bonded.

2. Related Art

In the manufacture of current semiconductor products, semiconductor wafers such as silicon wafers whose surface has a single crystal surface orientation are generally used. Particularly for LSI (Large Scale Integrated circuit) constituted by metal oxide semiconductor field effect transistors (MOSFET), using silicon wafers having {100} crystal surface orientation is mainstream.

It is known that, in a silicon wafer, electrons have greater mobility in the <110> direction of the {100} crystal surface orientation and holes in the <110> direction of the {110} crystal surface orientation. That is, the mobility of holes in the {100} crystal surface orientation is ½ to ¼ of that of electrons. To compensate for this imbalance, the channel width of pMOSFET using holes as carriers is designed to be wider than that of nMOSFET using electrons as carriers. With this design, the balance between a driving current of nMOSFET and that of pMOSFET is maintained and uniform circuit operations are ensured. However, another problem that the chip area of LSI increases due to wider pMOSFET arises.

On the other hand, the mobility of holes in the <110> direction in the {110} crystal surface orientation is about twice that of holes in the {100} crystal surface orientation. Therefore, compared with pMOSFET formed on the {100} surface, pMOSFET formed on the {110} surface shows a larger driving current. Unfortunately, however, the mobility of electrons in the {110} crystal surface orientation is significantly degraded compared with the {100} crystal surface orientation and therefore, driving capabilities of nMOSFET are degraded.

As described above, while silicon wafers whose surface has the {110} crystal surface orientation are superior in mobility of holes and thus are optimal for pMOSFET, they are not suitable for nMOSFET because of inferior mobility of electrons. Conversely, while silicon wafers whose surface has the {100} crystal surface orientation are superior in mobility of electrons and thus are optimal for nMOSFET, they are not suitable for pMOSFET because of inferior mobility of holes.

Thus, various technologies to create nMOSFET and pMOSFET each in an optimal crystal surface orientation by directly bonding two silicon wafers to create areas on the same silicon wafer surface having different crystal surface orientations have been proposed. That is, for example, technologies enabling high-performance and highly integrated LSI by creating areas of the {100} surface and the {110} surface on the same silicon wafer surface and forming nMOSFET on the {100} surface and pMOSFET on the {110} surface have been proposed.

U.S. Pat. No. 7,060,585 B1, for example, discloses as one such technology a method (ATR method: Amorphization/Templated Recrystallization method) of creating areas on the silicon wafer surface having different crystal surface orientations, by which silicon wafers having different crystal surface orientations on their surfaces are directly bonded and then ions of silicon or the like are injected to amorphize the upper silicon single crystal layer up to the bonding interface with the lower layer and the bonded wafers are annealed for recrystallization of the amorphized upper silicon layer based on crystal orientation information of the lower layer. Incidentally, a structure in which two silicon wafers are directly bonded without a thick oxide, as described above, is called a DSB (Direct Silicon Bonding structure) structure.

A method of manufacturing a semiconductor substrate having the conventional DSB structure will be described using FIG. 3. First, as shown in FIG. 3A, for example, a first silicon wafer (base wafer) 102 having the {100} surface orientation and a second silicon wafer (bond wafer) 104 having the {110} surface orientation are prepared. The two wafers have each a silicon oxide of about 0.7 nm formed on their surfaces by undergoing wet cleaning, for example, RCA cleaning. Next, as shown in FIG. 3B, the first silicon wafer 102 and the second silicon wafer 104 are contacted together in an atmospheric air at ordinary temperature. At this time, an interfacial silicon oxide 108 of about 1.4 nm is formed at the interface. Next, as shown in FIG. 3C, bonding heat treatment is performed at, for example, 500° C. or higher to increase bonded strength. Next, as shown in FIG. 3D, the second silicon wafer 104 is made thinner by grinding/polishing to form an upper silicon substrate layer 112. Also at this time, the interfacial oxide 108 is present on the semiconductor substrate 114. Next, as shown in FIG. 3E, interfacial oxide removal heat treatment is performed to remove the interfacial oxide 108. This heat treatment is performed, for example, in a reducing atmosphere at 1200° C. or so for several hours. A steep oxygen concentration gradient is formed from the interface toward the surface because oxygen out-diffusion from the surface of the thin upper silicon substrate layer 112 occurs during the heat treatment. Therefore, diffusion of oxygen from the interfacial silicon oxide 108 is promoted by the oxygen concentration gradient, leading to disappearance of the interfacial silicon oxide 108. Using the above method, as shown in FIG. 3F, a silicon substrate 114 in which the first silicon wafer (base wafer) 102 having the {100} surface orientation and the second silicon wafer (bond wafer) 104 having the {110} surface orientation are bonded at an interface 116 without silicon oxide is formed.

In the conventional manufacturing method, as described above, silicon wafers are bonded while there is a silicon oxide on the surface of silicon wafers because sufficient bonding strength cannot be maintained at ordinary temperature without silicon oxide. However, the conventional manufacturing method described above causes a problem of increased manufacturing costs because it becomes necessary to add a heat treatment process to remove the interfacial oxide.

### SUMMARY OF THE INVENTION

A method of manufacturing a semiconductor substrate in an aspect of the present invention comprises a process of preparing a first semiconductor wafer and a second semiconductor wafer, a process of bonding the first semiconductor wafer and second semiconductor wafer when a total of thickness of an oxide on the surface of the first semiconductor wafer and that of an oxide on the surface of the second semiconductor wafer is 0.4 nm or more and 1.0 nm or less, a process of providing heat treatment to a semiconductor substrate in which the first semiconductor wafer and second semiconductor wafer are bonded in an atmosphere of a reducing gas, an inert gas, or a mixed gas of a reducing gas and inert gas after the process of the bonding, and a process of making the first semiconductor wafer or the second semiconductor wafer thinner after the process of providing the heat treatment.

### BRIEF DESCRIPTION OF THE DRAWINGS

FIG. 1 is a diagram showing a manufacturing process flow of a semiconductor substrate in an embodiment.

FIG. 2 is a diagram showing relationships among a total thickness of silicon oxides in an example, a thickness of an interfacial oxide after heat treatment, and a void area.

FIG. 3 is a manufacturing process flow diagram of a semiconductor substrate of conventional technology.

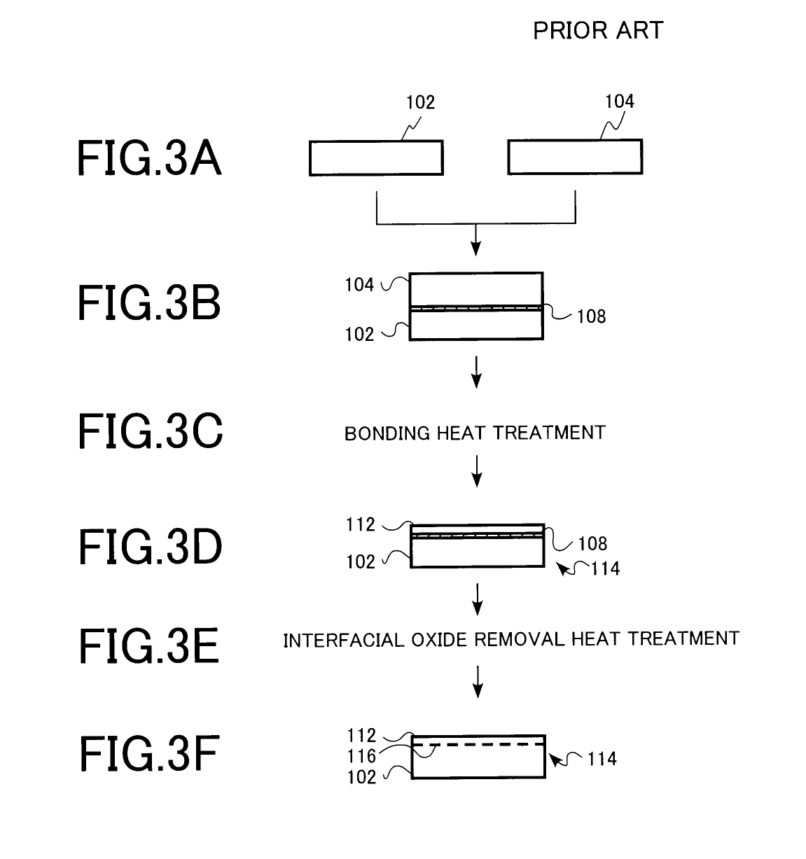

### DETAILED DESCRIPTION OF THE EMBODIMENTS

As described in BACKGROUND OF THE INVENTION, an interfacial oxide is removed in the conventional technology by making the bond wafer thinner after bonding the base wafer and bond wafer and then, using a steep oxygen concentration gradient formed during heat treatment inside a thin upper layer of the semiconductor substrate, which is a thinned area. The inventors focused on the possibility of removing an interfacial oxide by causing oxygen to dissolve into the semiconductor wafer, instead of diffusion of oxygen out of the wafer due to an oxygen concentration gradient. Then, the inventors found that an interfacial oxide can be removed within a range of sufficiently practical temperature and time of heat treatment by making the oxide on the wafer surface thinner before bonding without the need to make the bond wafer thinner before heat treatment.

Embodiments of a method of manufacturing a semiconductor substrate according to the present embodiment will be described below based on attached drawings. Though the embodiments will be described by taking as an example a case in which a silicon wafer is used as a semiconductor substrate, the present invention is not necessarily limited to the manufacturing method of a semiconductor substrate using silicon wafers. Moreover, herein the notation of the {100} surface and {110} surface will be used as a notation representing crystallographically equivalent surfaces to the (100) surface and (110) surface respectively. Then, the notation of the <100> direction and <110> direction will be used as a notation representing crystallographically equivalent directions to the [100] direction and [110] direction respectively.

### FIRST EMBODIMENT

A method of manufacturing a semiconductor substrate in the present embodiment comprises a process of preparing a first semiconductor wafer having the {100} surface orientation and a second semiconductor wafer having the {110} surface orientation, a process of making an oxide present on the surface of the first semiconductor wafer or the second semiconductor wafer thinner by etching using dilute HF (fluoric acid), a process of bonding the first semiconductor wafer and second semiconductor wafer when a total of thickness of a silicon oxide on the surface of the first semiconductor wafer and that of a silicon oxide on the surface of the second semiconductor wafer is 0.4 nm or more and 1.0 nm or less, and a process of providing heat treatment to a silicon substrate in which the first semiconductor wafer and second semiconductor wafer are bonded in an atmosphere of a reducing gas, an inert gas, or a mixed gas of a reducing gas and inert gas at 1000° C. or higher after the process of the bonding and before a process of making the first semiconductor wafer or the second semiconductor wafer thinner by polishing or the like. Here, the total of thickness is a sum of an average value of a silicon oxide thickness measured value of the first silicon wafer and that of an oxide thickness measured value of the second silicon wafer.

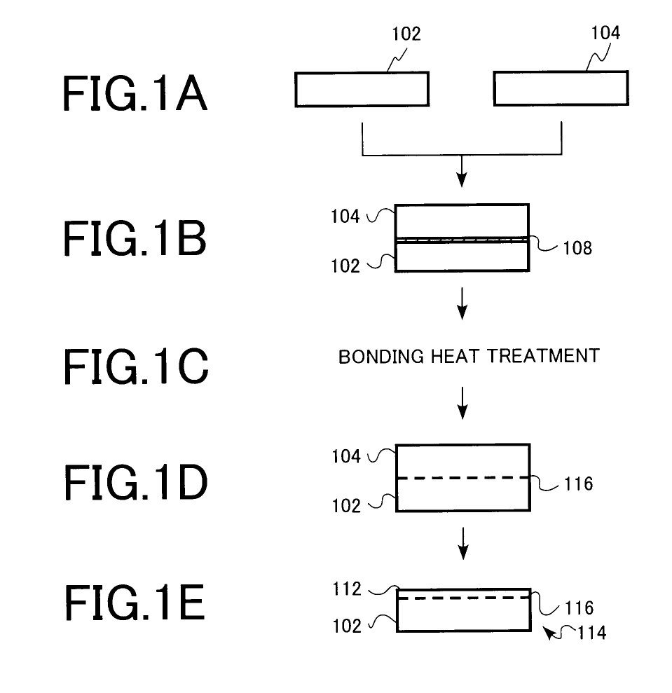

The method of manufacturing a semiconductor substrate in the present embodiment will be described more specifically below with reference to the manufacturing process flow diagram in FIG. 1. First, in a process shown in FIG. 1A, a silicon wafer is created by slicing a silicon single crystal ingot produced by, for example, the Czochralski method (CZ method) and having the crystal orientation {100} at a predetermined angle, for example, at an inclination (off angle) of 0 degree or more and 5 degrees or less, say, 0.2 degrees or so with respect to the {100} surface. Subsequently, the silicon wafer was cleansed by hydrogen fluoride-nitric acid and then mirror-polished. In this manner, the base wafer (first semiconductor wafer) 102 whose surface has the predetermined inclination (off angle) with respect to the {100} surface is prepared.

Next, similarly in the process shown in FIG. 1A, a silicon wafer is created by slicing a silicon single crystal ingot produced by, for example, the Czochralski method (CZ method) and having the crystal orientation {110} at a predetermined angle, for example, at an inclination (off angle) of 0 degree or more and 11 degrees or less, say, 8 degrees or so with respect to the {110} surface. Subsequently, the silicon wafer was cleansed by hydrogen fluoride-nitric acid and then mirror-polished. In this manner, the bond wafer (second semiconductor wafer) 104 whose surface has the predetermined inclination (off angle) with respect to the {110} surface is prepared.

Here, both or one of the base wafer 102 and the bond wafer 104 may be heat-treated using a heat treatment apparatus such as a batch-type vertical heat treating furnace or a single wafer RTP (Rapid Thermal Processing) apparatus. This heat treatment is preferably performed in an atmosphere of a reducing gas, an inert gas, or a mixed gas of a reducing gas and inert gas at a temperature of 1025° C. or higher and 1300° C. or lower for a time of 30 seconds or more and 2 hours or less. This is because the surface of both or one of silicon wafers is planarized by the heat treatnent, improving planarization at a bonding interface of two wafers. Thus, lattice defects at the interface after bonding is inhibited from appearing and when areas having different crystal surface orientations are created on the surface of a manufactured silicon substrate through amorphization of the silicon substrate by ion injection and recrystallization by annealing (ATR method), it becomes possible to inhibit lattice defects originating from lattice defects at the bonding interface from appearing.

The inclination with respect to the {100} surface is set to 0 degree or more and 5 degrees or less and that with respect to the {110} surface is set to 0 degree or more and 11 degrees or less because, if these ranges are exceeded, an effect of increased mobility of carriers may not be sufficiently received by each of nMOSFET and pMOSFET. Also, if these ranges are exceeded and the planarization heat treatment before bonding described above is added, a lattice defect inhibition effect may not be sufficiently exercised because formation of a step structure in which a flat surface of the wafer surface becomes a crystal plane becomes difficult, causing deterioration of surface smoothness of the wafer surface. Particularly, in view of surface smoothness, it is preferable that the inclination with respect to the {110} surface be 0 degree or more and 0.12 degrees or less, or 5 degrees or more and 11 degrees or less.

Also, it is desirable that surface roughness of the base wafer 102 and the bond wafer 104 be 0.5 nm or less in terms of RMS (Root Mean Square). RMS is preferably 0.2 nm or less. It becomes possible to reduce the surface roughness to 0.5 nm or less by applying the mirror-polishing to a wafer after being cut out by slicing or performing the planarization heat treatment before bonding under conditions of a hydrogen gas atmosphere, 1200° C., and 1 hour. RMS in this case can adopt, for example, a value obtained by measuring an arbitrary range of 10×10 μm² on the wafer surface by means of AFM (Atomic Force Microscope). The surface roughness is limited in this manner because an occurrence of interfacial voids in heat treatment after bonding together can be inhibited more effectively.

Then, treatment is provided so that the total of thickness of a silicon oxide on the surface of the base wafer 102 and that of a silicon oxide on the surface of the bond wafer 104 becomes 0.4 nm or more and 1.0 nm or less. More specifically, first a silicon oxide (chemical oxide) of about 0.7 nm is formed on the surface of each of both wafers by performing wet cleaning, for example, RCA cleaning (SC-1 treatment+SC-2 treatment) after the mirror-polishing. Then, subsequently, the silicon oxide of each of both wafers is made thinner to about 0.2 nm by etching (etchback) using, for example, dilute HF (fluoric acid) whose dilution ratio is about 0.01%. Accordingly, the total thickness can be made to be about 0.4 nm.

Here, the total thickness is limited to 0.4 nm or more and 1.0 nm or less because, if this range is exceeded, it becomes difficult to remove an interfacial silicon oxide by heat treatment. If the total length falls short of this range, on the other hand, bonding strength at ordinary temperature will be insufficient. In addition, an occurrence of voids after bonding process will be conspicuous.

Incidentally, a method of forming a silicon oxide on both surfaces of the base wafer 102 and the bond wafer 104 is shown here, but in the present invention, a silicon oxide may be present on the surface of only one both wafers as long as the total thickness is 0.4 nm or more and 1.0 nm or less. The method by etchback is adopted because it is difficult to control the thickness of chemical oxide to 1 nm or less by wet cleaning, but if a thin film can be controllably formed, etchback by a dilute HF solution is not necessarily needed.

Next, in a process shown in FIG. IB, the base wafer 102 and the bond wafer 104, the total thickness of whose silicon oxides on the surface thereof is 0.4 nm or more and 1.0 nm or less, are piled and brought into close contact, for example, at ordinary temperature and atmospheric pressure. In this process, the surfaces of two silicon wafers are brought into contact in a clean atmosphere at ordinary temperature and two silicon wafers can be bonded without using an adhesive or the like thanks to bonding of Si atoms via the OH group.

Next, in a process shown in FIG. 1C, bonding heat treatment is performed to increase bonding strength between the base wafer 102 and the bond wafer 104. With this bonding heat treatment, bonding strength is increased through direct bonding between Si atoms.

Also, as shown in FIG. 1D, a major feature of the present embodiment is to cause the interfacial silicon oxide 108 present at the bonding interface to disappear by the heat treatment. The bonding heat treatment is performed, for example, by using a vertical heat treating furnace, in an atmosphere of a reducing gas, an inert gas, or a mixed gas of a reducing gas and inert gas, for example, in an atmosphere of a hydrogen gas at a temperature of, for example, 1000 ° C. to 1300° C. or so for a processing time of, for example, about 30 minutes to 3 hours. Though bonding heat treatment at a temperature lower than 1000° C. is not necessarily excluded in the present invention, such bonding heat treatment is not preferable in view of enhancement of bonding strength and a longer heat treatment time required for the interfacial silicon oxide 108 to disappear. Moreover, a reducing gas, an inert gas, or a mixed gas of a reducing gas and inert gas is selected as an atmosphere because, if an oxidizing gas mingles, removal of the interfacial silicon oxide 108 becomes extremely difficult.

Next, as shown in FIG. 1E, the surface of the silicon substrate 114 on the bond wafer side is made thinner by grinding or polishing to form the silicon substrate 114 in which the upper silicon substrate layer 112 whose crystal surface orientation is substancialy {110} and the base wafer 102 whose crystal surface orientation is substancialy {100} are bonded at the interface 116 without silicon oxide.

According to the method of manufacturing a semiconductor substrate in the present embodiment, interfacial oxide removal heat treatment after making the bond wafer thinner, which has conventionally been necessary, can be omitted and an effect of a reduced manufacturing process of a semiconductor substrate having DSB bonding and thereby reduced manufacturing costs is gained. Also, with the omission of interfacial oxide removal heat treatment for causing an interfacial oxide to disappear by diffusion of oxygen from the wafer surface, it becomes possible to inhibit an occurrence of slips due to thermal stress particularly when the wafer has an increasingly larger diameter.

Examples of the present invention will be described below with reference to drawings, but the present invention is not limited by these examples.

A silicon single crystal ingot measuring 8 inches and having the crystal surface orientation (100) was fabricated by the Czochralski method (CZ method). The ingot is a p-type silicon single crystal with boron as impurities and having resistivity of 9 to 22 Ωcm. The silicon single crystal ingot was sliced in such a way that the off angle with respect to the (100) surface becomes 0.2 degrees to prepare a base wafer. Similarly, a silicon single crystal ingot measuring 8 inches and having the crystal surface orientation (110) was fabricated by the Czochralski method (CZ method). The ingot is a p-type silicon single crystal with boron as impurities and having resistivity of 9 to 22 Ωcm. The silicon single crystal ingot was sliced in such a way that the off angle with respect to the (110) surface becomes 8 degrees to prepare a bond wafer.

Next, the base wafer and bond wafer obtained by slicing were cleaned by hydrogen fluoride-nitric acid and then mirror-polished. Then, the base wafer and bond wafer underwent RCA cleaning. Surface roughness of the silicon wafers at this time was about 0.1 nm (measuring range: 10×10 Amp) in terms of RMS based on measurement by AFM. Then, the thickness of oxides before bonding was controlled by etching of a silicon oxide (chemical oxide) formed by the RCA cleaning of about 0.7 nm using 0.01% dilute HF (fluoric acid) diluted by water. By changing the etching time, combinations of wafers producing a total of thickness of a silicon oxide on the base wafer surface and that of a silicon oxide on the bond wafer surface between 0.2 nm and 1.4 nm were prepared. Here, the thickness of a silicon oxide on the wafer surface was measured by an ellipsometer and an average value thereof was determined.

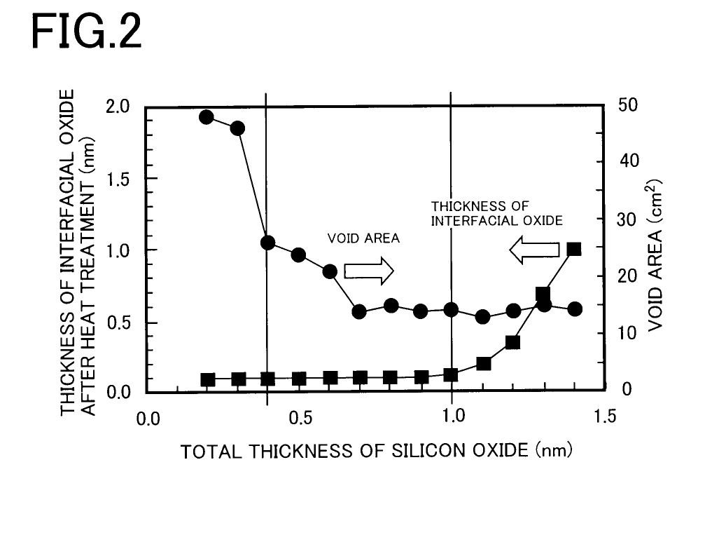

The base wafer and bond wafer were glued together in an atmospheric air at ordinary temperature. Then, as bonding heat treatment after bonding, heat treatment was performed in an atmosphere of a hydrogen gas at 1000° C. for 1 hour. The thickness of interfacial silicon oxides at a bonded interface of bonded silicon substrates of various conditions were evaluated using a cross section TEM. Also, the ultrasonic flaw detection was used to evaluate voids at the glued interface and to calculate a void area for the wafer. Results are shown in FIG. 2.

As is evident from FIG. 2, the interfacial oxide thickness after heat treatment is stable with 0.1 nm or less when the total thickness is in the range of 0.4 nm or more and 1.0 nm or less and the oxide is almost completely removed. In addition, under the conditions of the total thickness of 0.4 nm, no sharp increase in void area is recorded. Therefore, an effect by the present invention is verified.

### SECOND EMBODIMENT

A method of manufacturing a semiconductor substrate in the present embodiment is the same as that in the first embodiment except that after a silicon oxide on the surface is removed by dilute HF treatment for controlling the total of thickness of a silicon oxide on the surface of the base wafer 102 and that of a silicon oxide on the surface of the bond wafer 104 to 0.4 nm or more and 1.0 nm or less, a native oxide is grown by leaving the wafers alone, for example, in an atmosphere at ordinary temperature and thus, a description thereof is omitted.

When forming a silicon oxide on the surface of both or one of the base wafer 102 and the bond wafer 104, the silicon oxide can be formed very easily according to formation of a native oxide by leaving wafers alone after dilute HF treatment. Therefore, in addition to the operation effect of the first embodiment, it becomes possible to further reduce the manufacturing process and manufacturing costs. Incidentally, when forming a native oxide, the time and atmosphere in which wafers are left alone must be managed so that the total thickness should not exceed 1 nm.

However, compared with the first embodiment, bonding strength at ordinary temperature and a void occurrence inhibition effect after high-temperature heat treatment in the present embodiment deteriorate. This can be considered as follows: First, when an oxide is present on the surface of silicon wafers, wafers at ordinary temperature are bonded via the OH group at the wafer surface. Thus, a pure silicon surface without silicon oxide has only a small amount of OH group and cannot maintain sufficient bonding strength at ordinary temperature. Homogeneity of the surface of a naturally formed wafer is low and there are some areas where there is no silicon oxide or an extremely thin silicon oxide is present. Thus, bonding strength in such areas will be somewhat weaker. If a silicon oxide is present at an interface when high-temperature heat treatment is performed to increase bonding strength, the interfacial silicon oxide absorbs H₂O and H₂ evaporated at the interface. Thus, an occurrence of voids at the interface can be inhibited. However, a native oxide has on the wafer surface areas where there is no silicon oxide or an extremely thin silicon oxide is present. Thus, absorption of H₂O and H₂ is limited, making complete inhibition of void occurrence difficult.

From the above aspects, operation effects of the present invention will become still more pronounced if homogeneity of silicon oxides formed on wafer surfaces before bonding is enhanced. That is, the average thickness of an interfacial silicon oxide can be made thinner by enhanced thickness homogeneity, making possible removal of the interfacial silicon oxide by shorter heat treatment at a lower temperature. Further, since an area where there is no silicon oxide or an extremely thin silicon oxide is present is less likely to exist, bonding strength at ordinary temperature is enhanced. Also, since absorption of H₂O and H₂ is less likely to be limited, an occurrence of voids after high-temperature heat treatment is inhibited.

### THIRD EMBODIMENT

A method of manufacturing a semiconductor substrate in the present embodiment is the same as that in the first embodiment except that a silicon oxide is formed by the ALD (Atomic Layer Deposition) method for controlling the total of thickness of an oxide on the surface of the first semiconductor wafer and that of an oxide on the surface of the second semiconductor wafer to 0.2 nm or more and 1.0 nm or less and thus, a description thereof is omitted.

If the ALD method is used when a silicon oxide is formed on the surface of both or one of the base wafer 102 and the bond wafer 104, an extremely homogeneous and thin silicon oxide can be formed. Therefore, in addition to the operation effect of the first embodiment, it becomes possible to make the total thickness of silicon oxides still thinner and reduce the temperature/time for bonding heat treatment, which also serves as interfacial oxide removal heat treatment, by using its high homogeneity.

### FOURTH EMBODIMENT

A method of manufacturing a semiconductor substrate in the present embodiment is the same as that in the first embodiment except that a silicon oxide is formed by the CVD (Chemical Vapor Deposition) method for controlling the total of thickness of an oxide on the surface of the first semiconductor wafer and that of an oxide on the surface of the second semiconductor wafer to 0.4 nm or more and 1.0 nm or less and thus, a description thereof is omitted.

If the CVD method is used when a silicon oxide is formed on the surface of both or one of the base wafer 102 and the bond wafer 104, an extremely homogeneous and thin silicon oxide can be formed. Therefore, in addition to the operation effect of the first embodiment, it becomes possible to make the total oxide thickness still thinner and reduce the temperature/time for bonding heat treatment, which also serves as interfacial oxide removal heat treatment, by using its high homogeneity. Though thickness homogeneity is somewhat inferior compared with the ALD method, manufacturing costs of semiconductor substrate can be reduced more than the ALD method because of process costs thereof.

### FIFTH EMBODIMENT

A method of manufacturing a semiconductor substrate in the present embodiment is the same as that in the first to fourth embodiments except that the crystal surface orientation of the first silicon wafer and that of the second silicon wafer are the same, for example, as the (100) surface or the (110) surface and thus, a description thereof is omitted.

According to the present embodiment, a method of manufacturing a silicon substrate in which wafers having the same surface orientation are DSB-bonded used, for example, in MEMS (Micro Electro Machinery Systems) that can simplify the manufacturing process and reduce manufacturing costs can be provided.

Embodiments of the present invention have been described with reference to concrete examples. Though descriptions of parts that were not directly necessary to describe the present invention such as a semiconductor substrate and a method of manufacturing a semiconductor substrate were omitted when describing the embodiments, necessary components related to the semiconductor substrate or the method of manufacturing a semiconductor substrate can appropriately be selected and used.

For example, the above embodiments have been described assuming that silicon (Si) is used as a semiconductor material for the first semiconductor wafer and second semiconductor wafer. However, it is also possible to select any semiconductor material including SiC, SiGe, SiGeC, Ge, GaAs, InAs, InP, and multiple-unit conductors of III/V group or II/VI group.

In addition, all methods of manufacturing a semiconductor substrate that have components of the present invention and whose design can be appropriately modified by a person skilled in the art are included in the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents

What is claimed is:

1. A method of manufacturing a semiconductor substrate; comprising:
preparing a first semiconductor wafer and a second semiconductor wafer;
bonding the first semiconductor wafer and the second semiconductor wafer while a total thickness of an oxide on a surface of the first semiconductor wafer and that of an oxide on the surface of the second semiconductor wafer is 0.4 nm or more and 1.0 nm or less;
after performing the bonding, providing heat treatment to a semiconductor substrate in which the first semiconductor wafer and the second semiconductor wafer are bonded in an atmosphere of a reducing gas, an inert gas, or a mixed gas of a reducing gas and inert gas; and
after performing the heat treatment, making the first semiconductor wafer or the second semiconductor wafer thinner.

2. The method according to claim 1, wherein the first semiconductor wafer and the second semiconductor wafer are silicon wafers.

3. The method according to claim 1, wherein before performing the bonding, an oxide present on the surface of the first semiconductor wafer or the second semiconductor wafer is made thinner by etching using dilute HF (fluoric acid).

4. The method according to claim 1, wherein a heat treatment temperature at which the heat treatment is performed is 1000 degrees or higher.

5. The method according to claim 2, wherein one of a crystal surface orientation of the surface of the first semiconductor wafer and that of the surface of the second semiconductor wafer has an inclination (off angle) in a range of 0 degree or more and 5 degrees or less with respect to a {100} surface and the other crystal surface orientation has the inclination (off angle) in the range of 0 degree or more and 0.12 degrees or less, or 5 degrees or more and 11 degrees or less with respect to a {110} surface.

6. The method according to claim 1, wherein the oxide on the surface of the first semiconductor wafer and that on the surface of the second semiconductor wafer are native oxides grown in an atmospheric air.

7. The method according to claim 1, wherein the oxide on the surface of the first semiconductor wafer and that on the surface of the second semiconductor wafer are oxides formed by an ALD (Atomic Layer Deposition) method.

8. The method according to claim 1, wherein the oxide on the surface of the first semiconductor wafer and that on the surface of the second semiconductor wafer are oxides formed by a CVD (Chemical Vapor Deposition) method.

9. The method according to claim 2, wherein a crystal surface orientation of the surface of the first semiconductor wafer and that of the surface of the second semiconductor wafer have both an inclination (off angle) in a range of 0 degree or more and 5 degrees or less with respect to a {100} surface.

10. The method according to claim 2, wherein a crystal surface orientation of the surface of the first semiconductor wafer and that of the surface of the second semiconductor wafer have both an inclination (off angle) in a range of 0 degree or more and 0.12 degrees or less, or 5 degrees or more and 11 degrees or less with respect to a {110} surface.

11. The method according to claim 1, wherein the first semiconductor wafer or the surface of the second semiconductor wafer is made thinner by wafer polishing.
